(19) United States
(12) Patent Application Publication
(10) Pub. No.: US 2026/0336420 A1
(43) Pub. Date: Oct. 29, 2026

(54) DEVICE AND METHOD FOR DETERMINING A COOLANT TEMPERATURE OF A COOLING CIRCUIT

(71) Applicant: Robert Bosch GmbH, Stuttgart (DE)

(72) Inventors: Koji Rudolf Jaeger, Kanagawa (JP); Julia Bihlmaier, Stuttgart (DE); Markus Michels, Stuttgart (DE)

(21) Appl. No.: 19/103,779

(22) PCT Filed: Jun. 27, 2023
(86) PCT No.: PCT/EP2023/067459

§ 371 Date: Feb. 13, 2025

(30) Foreign Application Priority Data
Aug. 29, 2022 (DE) 10 2022 208 918.9

(51) Int. Cl. B60L 3/12; B60L 53/302; G01K 13/02; H05K 7/20

(52) U.S. Cl. CPC B60L 3/12; B60L 53/302; G01K 13/02; H05K 7/202; H05K 7/20927; B60L 2240/36

(57) ABSTRACT

A device (100) for determining a coolant temperature of a cooling circuit (300), wherein the cooling circuit (300) is configured to sequentially cool the power electronics of at least a first and a second power electronic component (510, 520). The device (100) is configured to receive and evaluate a signal during operation of the first component (510) to determine the coolant temperature of the cooling circuit (300) that characterizes the temperature of the power electronics of the switched off second component (520), and to receive and evaluate a signal during operation of the second component (520) to determine the coolant temperature of the cooling circuit (300) that characterizes the temperature of the power electronics of the switched off first component (510).

The invention relates to a device and method for determining a coolant temperature of a cooling circuit. Furthermore, the invention relates to an electric system, a drive train with a device, a vehicle with a drive train as well as a computer program and a machine-readable storage medium.

### PRIOR ART

Power electronic equipment, preferably in vehicles, such as chargers, DC voltage converters, inverters, and/or electric machines, generate waste heat in operation that is dissipated from the heat source by means of a coolant of a cooling circuit. Preferably, the heat sources are power electronic components, preferably circuit breakers. A corresponding implementation is known from the patent application WO 2017/182226 A1. To safely operate such power electronic equipment at its power limit, the temperature of the coolant must be known. If the coolant temperature exceeds a pre-determinable threshold, the heated coolant may no longer be capable of dissipating sufficient waste heat. Therefore, the device is subsequently switched off or its currently implemented power is reduced to the extent that the coolant temperature is lowered again and cooling of the power electronic components is enabled again. To determine the coolant temperature, temperature sensors that determine the temperature are placed on the cooling circuit or in the coolant. In order to reduce the installation space necessary for the temperature sensors, solutions are needed to determine the coolant temperature which allow for determination of the coolant temperature without the correspondingly arranged temperature sensors on the cooling circuit.

### DISCLOSURE OF THE INVENTION

A device for determining a coolant temperature of a cooling circuit is provided. The cooling circuit is configured to sequentially cool the power electronics of at least a first and a second power electronic component. The first component comprises a first sensor device for determining the temperature of the power electronics of the first component. The second component comprises a second sensor device for determining the temperature of the power electronics of the second component. The first component is at least temporarily switched on and its power electronics generate waste heat. At the same time, the second component is switched off. The device is configured to receive and evaluate a signal during operation of the first component to determine the coolant temperature of the cooling circuit that characterizes the temperature of the power electronics of the switched off second component, and to receive and evaluate a signal during operation of the second component to determine the coolant temperature of the cooling circuit that characterizes the temperature of the power electronics of the switched off first component.

Preferably, the coolant temperature is the temperature of the coolant in the cooling circuit, preferably the average temperature of the coolant in the cooling circuit. Preferably, the cooling circuit comprises a closed conduit system through which a cooling medium, cooling fluid, or coolant flows, wherein the coolant flows through a heat exchanger and is cooled there. Subsequently, the coolant flows though heat sources one after the other, reheating to be cooled again via the heat exchanger. Preferably, the heat sources or power electronic components are individual conductive electronic assemblies or devices that generate waste heat when turned on, preferably during operation, that is dissipated by way of the coolant flowing by. When the power electric components are off, preferably when they are not in operation, they do not generate waste heat. The first and second power electronic components may each be disposed in their own housing, preferably in a common housing, preferably spaced apart from one another on a common or on multiple printed circuit boards. Corresponding power electronic components include sensor devices for activation for determining the temperature of their power electronic components, preferably circuit breakers, capacitors, chokes or coils of an electric machine. Preferably, the sensor device for determining the temperature of the power electronics of the components is arranged in the direct vicinity of the power electronics thereof and allows for an accurate determination of the temperature of the power electronics of the component. Preferably, the power electronics are connected to the cooling circuit in a highly thermally conductive manner. Consequently, the power electronics rapidly assume the temperature of the coolant when it is not operating or when it is switched off, preferably permanently. To determine the coolant temperature, a signal is received and evaluated by the device, or a control device within the device, that characterizes the temperature of the switched off power electronic component. Preferably, the signal is received and evaluated from the switched off component or from the sensor device of the switched off component. The greater the distance of the sensor device considered to determine the coolant temperature from the actual heat source, the more precisely the actual coolant temperature of the cooling circuit can be determined. The influence of the heat source on the coolant temperature in the area of the sensor device to be considered decreases with increasing distance between the heat source and the sensor device to be considered. Preferably, the coolant temperature is determined when evaluating the signal. Preferably, the coolant temperature is determined from the received signal by means of a computing model. Preferably, the considered computing model depicts the heat transfer from the sensor device to the coolant. Preferably, if the coolant temperature exceeds a pre-determinable threshold and sufficient waste heat is no longer dissipated by the heated coolant, at least one component is switched off or its currently implemented power is reduced to the extent that the coolant temperature is reduced again and cooling of the power electronic components is enabled once again. Alternatively, the flow rate of the coolant is preferably increased or the coolant temperature is lowered by increasing the cooling efficiency of the heat exchanger located in the cooling circuit.

Advantageously, a simple device is provided that determines the coolant temperature of a cooling circuit. No additional components or construction space are required for this solution.

In another configuration, the first component is a charger and the power electronics of the first component comprise circuit breakers. Preferably, the first component is a charger for a vehicle to charge a high voltage battery connectable on the output side. Preferably, the first sensor device is arranged in direct proximity to the charger circuit breakers to determine the temperature of the power electronics of the first component and allows for an accurate determination of the temperature of the charger circuit breakers. Preferably, the circuit breakers, IGBT or MOSFET, are connected to the cooling circuit in a highly thermally conductive manner. Consequently, the circuit breakers rapidly assume the temperature of the coolant when not operating or when they are switched off, preferably permanently.

Advantageously, an embodiment of a first power electronic component is provided.

In another embodiment, the second component is a DC voltage converter or an inverter. The power electronics of the second component comprise circuit breakers. Preferably, the second component is a DC voltage converter for converting the high voltage of the high-voltage battery to a low voltage for supplying an on-board power supply of the vehicle. Preferably, the second sensor device is arranged in direct proximity to the DC voltage transformer circuit breakers to determine the temperature of the power electronics of the second component and allows for an accurate determination of the temperature of the DC voltage converter circuit breakers. Preferably, the circuit breakers, IGBT or MOSFET, are connected to the cooling circuit in a highly thermally conductive manner. Consequently, the circuit breakers rapidly assume the temperature of the coolant when not operating or when they are switched off, preferably permanently.

Advantageously, a configuration of a second power electronic component is provided.

Further, an electrical system is provided comprising at least a first and a second power electronic component, a common cooling circuit for sequential cooling of the power electronics of the first and second components, and a device for determining a coolant temperature of the cooling circuit. The first component comprises a first sensor device for determining the temperature of the power electronics of the first component and the second component comprises a second sensor device for determining the temperature of the power electronics of the second component. The first component is switched on at least temporarily and its power electronics generate waste heat, while the second component is simultaneously switched off and vice versa. The device is configured to receive and evaluate a signal during operation of the first component to determine the coolant temperature of the cooling circuit that characterizes the temperature of the power electronics of the switched off second component, and to receive and evaluate a signal during operation of the second component to determine the coolant temperature of the cooling circuit that characterizes the temperature of the power electronics of the switched off first component.

Advantageously, an electrical system is provided that determines the coolant temperature of a cooling circuit. No additional components or construction space are required for this solution.

Furthermore, the invention relates to a drive train with a device as described above, wherein the drive train comprises in particular a high voltage battery, an inverter and/or an electric machine. Advantageously, a drive train of an electric vehicle is provided having a device that determines the coolant temperature of a cooling circuit. No additional components or construction space are required for this solution.

The invention further relates to a vehicle having a drive train, as described above.

Advantageously, a vehicle is provided with a device that determines the coolant temperature of a cooling circuit. No additional components or construction space are required for this solution.

The invention further relates to a method for operating a device as presented above with the steps of:
receiving a signal characterizing the temperature of the power electronics of the switched off second power electronics during operation of the first component; evaluating the received signal and receiving a signal characterizing the temperature of the power electronics of the switched off first power electronics during operation of the second component;
evaluating (820) the received signal.

Advantageously, by receiving and evaluating the signal, a method is provided that determines the coolant temperature of a cooling circuit. No additional components or construction space are required for this solution.

The invention further relates to a computer program comprising commands which, when the program is executed by the device, cause it to carry out the method described.

The invention furthermore relates to a machine-readable memory medium comprising commands which, when executed by the device, cause it to carry out the method described.

It is understood that the features, properties, and advantages of the device apply or can be applied accordingly to the electrical system and the method or the drive train and the vehicle and vice versa.

Further features and advantages of embodiments of the invention are apparent from the following description with reference to the accompanying drawings.

### BRIEF DESCRIPTION OF THE DRAWINGS

The invention will be explained in further detail hereinafter with reference to the drawings:

FIG. 1 a schematic diagram of a vehicle with a drive train having a device,

FIG. 2 a schematic flow chart for a method for operating the device.

### EMBODIMENTS OF THE INVENTION

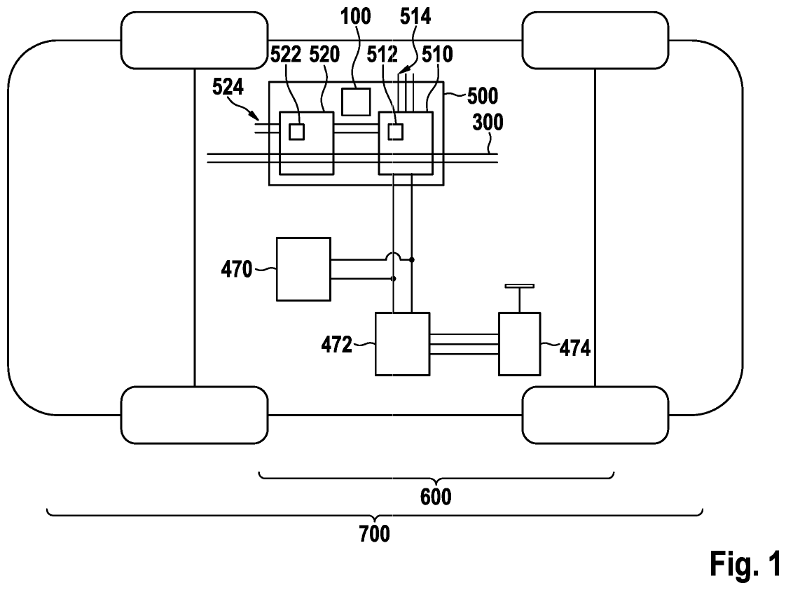

FIG. 1 shows a schematic diagram of a vehicle 700 having a drive train 600 with a device 100 and an exemplary electrical system 500. The vehicle 700 is in this case shown (only by way of example) as comprising four wheels, wherein the invention can be used equally in any vehicle with any desired number of wheels on land, on water, and in the air. The exemplary drive train 600 shown comprises at least the device 100. Further, preferably, the drive train comprises a first and second power electronic components 510, 520 having a cooling circuit 300 or an electrical system 500, a battery 470, an inverter 472, and/or an electrical machine 474. The device 100 is configured to determine a coolant temperature of the coolant in the cooling circuit 300. The cooling circuit 300 is configured to sequentially cool the power electronics of at least the first and second power electronic components 510, 520. Only a portion of the cooling circuit 300 is shown in FIG. 1 for clarity of illustration. Preferably, the cooling circuit is a closed system in which the coolant flows and circulates in one direction. The first component 510 comprises a first sensor device 512 for determining the temperature of the power electronics of the first component 510. By way of example, the first component 510 is shown as a charger, preferably having an input terminal 514 for connecting a single-phase or multi-phase AC voltage source for charging the battery or high-voltage battery 470 connectable on the output side. Charging of the battery by means of the AC voltage source is preferably carried out when the vehicle is at a standstill. The second component 520 comprises a second sensor device 522 for determining the temperature of the power electronics of the second component 520. By way of example, the second component 520 is shown as a DC voltage converter, preferably with a low voltage terminal 524, to which preferably the on-board power supply and a low voltage battery of a vehicle are connected. By means of the DC voltage converter, the on-board power system is preferably supplied with the power from the high-voltage network or the high-voltage battery, wherein the high input voltage is converted to the low-voltage of the on-board power system. Preferably, the low-voltage network is supplied by means of the DC voltage converter while the vehicle is traveling. Thus, preferably when the vehicle is at a standstill, the first component 510 is switched on and the second component 520 is switched off and while the vehicle is traveling, the first component 510 is switched off and the second component 520 is switched on. Thus, at least intermittently, the first component 510 is switched on and its power electronics generate waste heat and simultaneously the second component 520 is switched off and vice versa. The device 100 is configured to receive and evaluate a signal characterizing the temperature of the power electronics of the switched off second component 520 during operation of the first component 510 to determine the coolant temperature of the cooling circuit 300. Further, during operation of the second component 520, the device 100 is configured to receive and evaluate a signal characterizing the temperature of the power electronics of the switched off first component 510 to determine the coolant temperature of the cooling circuit 300. Preferably, the device 100 receives the signal via a line directly from one of the components or via a BUS system; wireless transmission of the signal is also possible. The signal is preferably the signal of the sensor device; a further processed signal which characterizes the temperature of the switched off power electronics is also possible. Preferably, the coolant temperature is determined when evaluating the signal. The evaluation of the signal preferably comprises the direct further use of the signal or comprises an evaluation, which can comprise filtering, an offset displacement, an application of a computational model, or further signal processing steps. The electrical system 500 comprises at least the first and second power electronic components 510, 520, the common cooling circuit 300, preferably a common cooling circuit section, for sequential cooling of the power electronics of the first and second components 510, 520, and the device 100 for determining the coolant temperature of the cooling circuit 300. By way of example, the electrical system 500 is shown as a combination of a charger and a DC voltage converter, preferably within a housing.

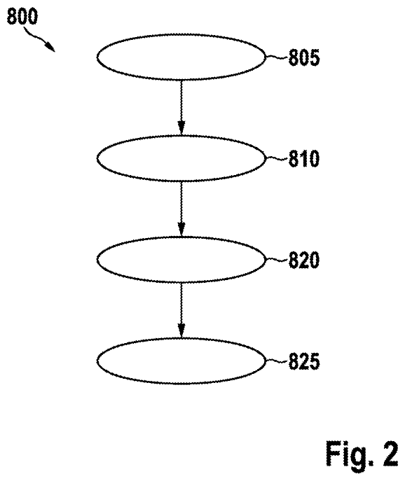

FIG. 2 shows a schematic flow chart for a method 800 for operating the device 100. The method 800 starts with step 805. In step 810, a signal is received that characterizes the temperature of the switched off power electronics. In step 820, the received signal is evaluated. Preferably, the coolant temperature is determined when evaluating the signal. The method ends at step 825.

1. A device (100) for determining a coolant temperature of a cooling circuit (300),
wherein the cooling circuit (300) is configured to sequentially cool the power electronics of at least a first and a second power electronic component (510, 520),
wherein the first component (510) comprises a first sensor device (512) for determining the temperature of the power electronics of the first component (510) and the second component (520) comprises a second sensor device (522) for determining the temperature of the power electronics of the second component (520),
wherein the first component (510) is switched on at least temporarily and its power electronics generate waste heat, and simultaneously the second component (520) is switched off, and vice versa,
wherein
the device (100) is configured
to receive and evaluate a signal during operation of the first component (510) to determine the coolant temperature of the cooling circuit (300) that characterizes the temperature of the power electronics of the switched off second component (520)
and to receive and evaluate a signal during operation of the second component (520) to determine the coolant temperature of the cooling circuit (300) that characterizes the temperature of the power electronics of the switched off first component (510).

2. The device according to claim 1, wherein the first component (510) is a charger and the power electronics of the first component (510) comprises circuit breakers.

3. The device according to claim 1, wherein the second component (520) is a DC voltage converter or inverter (472) and the power electronics of the second component (520) comprises circuit breakers.

4. An electrical system (500) comprising
at least a first and a second power electronic component (510, 520),
a common cooling circuit (300) for sequentially cooling the power electronics of the first and second components (510, 520), and a device (100) for determining a coolant temperature of the cooling circuit (300),
wherein the first component (510) comprises a first sensor device (512) for determining the temperature of the power electronics of the first component (510) and the second component (520) comprises a second sensor device (522) for determining the temperature of the power electronics of the second component (520),
wherein the first component (510) is switched on at least temporarily and its power electronics generate waste heat, and simultaneously the second component (520) is switched off, and vice versa,
wherein
the device (100) is configured for this purpose,
to receive and evaluate a signal during operation of the first component (510) to determine the coolant temperature of the cooling circuit (300) that characterizes the temperature of the power electronics of the switched off second component (520)
and to receive and evaluate a signal during operation of the second component (520) to determine the coolant temperature of the cooling circuit (300) that characterizes the temperature of the power electronics of the switched off first component (510).

5. A drive train (600) having a device (100) according to claim 1, wherein the drive train (600) comprises a high voltage battery (470), an inverter (472), and/or an electrical machine (474).

6. A vehicle (700) having a drive train (600) according to claim 5.

7. A method (800) for determining a coolant temperature of a cooling circuit (300) having a device (100) according to claim 1, comprising the steps of:
during operation of the first component (510),
receiving (810) a signal characterizing the temperature of the power electronics of the switched off second power electronics;
evaluating (820) the received signal, and
during operation of the second component (520), receiving (810) a signal characterizing the temperature of the power electronics of the switched off first power electronics;
evaluating (820) the received signal.

8. (canceled)

9. A non-transitory, machine-readable storage medium comprising commands which, when executed by a computer, cause the computer to determine a coolant temperature of a cooling circuit (300) having a device (100),
wherein the cooling circuit (300) is configured to sequentially cool power electronics of at least a first and a second power electronic component (510, 520),
wherein the first component (510) comprises a first sensor device (512) for determining the temperature of the power electronics of the first component (510) and the second component (520) comprises a second sensor device (522) for determining the temperature of the power electronics of the second component (520),
wherein the first component (510) is switched on at least temporarily and its power electronics generate waste heat, and simultaneously the second component (520) is switched off, and vice versa,
by:
during operation of the first component (510), receiving (810) a signal characterizing the temperature of the power electronics of the switched off second power electronics;
evaluating (820) the received signal, and
during operation of the second component (520), receiving (810) a signal characterizing the temperature of the power electronics of the switched off first power electronics;
evaluating (820) the received signal.
